(19) United States
(12) Patent Application Publication
(10) Pub. No.: US 2026/0202737 A1
(43) Pub. Date: Jul. 16, 2026

(54) A POD FOR A PATTERNING DEVICE

(71) Applicant: ASML Netherlands B.V., Veldhoven (NL)

(72) Inventor: Robert Jeffrey WADE, Stamford, CT (US)

(73) Assignee: ASML Netherlands B.V., Veldhoven (NL)

(21) Appl. No.: 19/134,983

(22) PCT Filed: Nov. 28, 2023
(86) PCT No.: PCT/EP2023/083405

§ 371 Date: Jun. 2, 2025

Related U.S. Application Data
(60) Provisional application No. 63/435,180, filed on Dec. 23, 2022.

(51) Int. Cl. G03F 1/66; G03F 7/00; H10P 72/10

(52) U.S. Cl. CPC G03F 1/66; G03F 7/70741; G03F 7/70841; H10P 72/1906

(57) ABSTRACT

A system includes a first container and a second container. The first container receives a patterning device and maintains a predetermined environment inside the first container. The second container receives the first container and maintains a vacuum inside the second container. The second container includes a flange, a first end, and a second end. The flange is located on an exterior of the second container. The second container can be gripped and transported via the flange. The first end includes a vacuum valve and a purge valve. The vacuum valve facilitates removal of gas from the second container. The purge valve facilitates introduction of gas into the second container. The vacuum valve and the purge valve interface with a first external vacuum environment. The second end opposite the first end and the second end has an opening. The opening allows the removal of the first container from the second container.

### CROSS-REFERENCE TO RELATED APPLICATION

This application claims priority of U.S. application 63/435,180 which was filed on 23 Dec. 2022 and which is incorporated herein in its entirety by reference.

### FIELD

The present disclosure relates to a pod for a patterning device, for example, an outer pod for handling a reticle stored in an inner pod in lithographic apparatuses and systems.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include sσ-called steppers, in which each target portion is irradiated by exposing an entire pattern onto the target portion at one time, and sσ-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

During lithographic operation, different processing steps may require different layers to be sequentially formed on the substrate. Accordingly, it can be necessary to position the substrate relative to prior patterns formed thereon with a high degree of accuracy. Generally, alignment marks are placed on the substrate to be aligned and are located with reference to a second object. A lithographic apparatus may use an alignment apparatus for detecting positions of the alignment marks and for aligning the substrate using the alignment marks to ensure accurate exposure from a mask. Misalignment between the alignment marks at two different layers is measured as overlay error.

In order to monitor the lithographic process, parameters of the patterned substrate are measured. Parameters may include, for example, the overlay error between successive layers formed in or on the patterned substrate and critical linewidth of developed photosensitive resist. This measurement can be performed on a product substrate and/or on a dedicated metrology target. There are various techniques for making measurements of the microscopic structures formed in lithographic processes, including the use of scanning electron microscopes and various specialized tools. A fast and non-invasive form of a specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Spectroscopic scatterometers direct a broadband radiation beam onto the substrate and measure the spectrum (intensity as a function of wavelength) of the radiation scattered into a particular narrow angular range. By contrast, angularly resolved scatterometers use a monochromatic radiation beam and measure the intensity of the scattered radiation as a function of angle.

Such optical scatterometers can be used to measure parameters, such as critical dimensions of developed photosensitive resist or overlay error (OV) between two layers formed in or on the patterned substrate. Properties of the substrate can be determined by comparing the properties of an illumination beam before and after the beam has been reflected or scattered by the substrate.

A lithography apparatus may include a supply chain and transfer mechanism for reticles. Reticles may be moved from a non-vacuum environment to a vacuum environment. For example, reticles may be stored in a pod and moved from a customer (non-vacuum environment) to a lithography apparatus (vacuum environment).

The pod may be a specialized enclosure designed to securely and safely hold reticles in a controlled environment. Some conventional extreme ultraviolet (EUV) outer pods may not maintain vacuum. This can lead to extra steps when moving a reticle placed in an inner pod, such as an EUV inner pod (EIP) from the customer, into the vacuum environment of the lithography apparatus. For example, the outer pod may not meet a desired cleanliness for an automated handling machine. In addition, there may be an increase in a risk of contamination of the EIP and reticle and cost due to the extra equipment used to transfer the pod from the non-vacuum environment to the vacuum environment. Contamination (e.g., a particle during exposure) may lead to wafer lead issues.

### SUMMARY

Accordingly, it is desirable to improve performance and cleanliness. For example, there is a desired to provide an outer pod that maintains vacuum as discussed in embodiments described herein.

In some embodiments, a system includes a first container and a second container. The first container receives a patterning device and maintains a predetermined environment inside the first container. The second container receives the first container and maintains a vacuum inside the second container. The second container includes a flange, a first end, and a second end. The flange is located on an exterior of the second container. The second container can be gripped and transported via the flange. The first end includes a vacuum valve and a purge valve. The vacuum valve facilitates removal of gas from the second container. The purge valve facilitates introduction of gas into the second container. The vacuum valve and the purge valve interface with a first external vacuum environment. The second end is opposite the first end and the second end has an opening. The opening allows the removal of the first container from the second container.

In some embodiments, a method includes receiving a patterning device in a first container, maintaining the first container at a predetermined environment, receiving the first container in a second container, maintaining the second container at a vacuum amount, transporting the second container via a flange locating on an exterior of the second container, removing gas from the second container through a vacuum valve that interfaces with a first external vacuum environment, introducing gas into the second container through purge valve that interfaces with the first external vacuum environment, and removing the first container from the second container through an opening.

In some embodiments, an outer pod includes an outer shell, a flange, an end, and an access door. The flange is located on an exterior of the outer shell. The outer pod is gripped and transported via the flange. The first end has an opening. The opening is configured to allow removal of an inner pod stored in the outer pod and to interface with an external vacuum environment. The access seals the opening.

Further features of the present disclosure, as well as the structure and operation of various embodiments, are described in detail below with reference to the accompanying drawings. It is noted that the present disclosure is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE FIGURES

The accompanying drawings, which are incorporated herein and form part of the specification, illustrate the present disclosure and, together with the description, further serve to explain the principles of the present disclosure and to enable a person skilled in the relevant art(s) to make and use embodiments described herein.

FIG. 1A shows a schematic of a reflective lithographic apparatus, according to some embodiments.

FIG. 1B shows a schematic of a transmissive lithographic apparatus, according to some embodiments.

FIG. 2 shows a more detailed schematic of the reflective lithographic apparatus, according to some embodiments.

FIG. 3 shows a schematic of a lithographic cell, according to some embodiments.

FIG. 4 shows a schematic of a handling system, according to some embodiments.

FIGS. 5A and 5B show schematics of an outer pod, according to some embodiments.

FIG. 6 shows a schematic of an outer pod with a removable access door, according to some embodiments.

FIG. 7A shows a schematic of an outer pod with a rotary door, according to some embodiments.

FIG. 7B shows a schematic of a cross-sectional view of the outer pod of FIG. 7A, according to some embodiments.

FIG. 8A shows a schematic of an outer pod with a rotary door, according to some embodiments.

FIG. 8B shows a schematic of the outer pod of FIG. 8A with access door in a lifted position, according to some embodiments.

FIG. 8C shows a schematic of a cross-sectional view of the outer pod in FIGS. 8A and 8B, according to some embodiments.

FIG. 9 shows a schematic of an outer pod, according to some embodiments.

FIG. 10 shows a schematic of a handling system, according to some embodiments.

FIG. 11 a flowchart of a method for handling inner pods, according to some embodiments.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as tσ-scale drawings.

### DETAILED DESCRIPTION

This specification discloses one or more embodiments that incorporate the features of the present disclosure. The disclosed embodiment(s) are provided as examples. The scope of the present disclosure is not limited to the disclosed embodiment(s). Claimed features are defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., +10%, +20%, or +30% of the value).

Embodiments of the disclosure can be implemented in hardware, firmware, software, or any combination thereof. Embodiments of the disclosure may also be implemented as instructions stored on a machine-readable medium, which can be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions can be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present disclosure can be implemented.

### Example Lithographic Systems

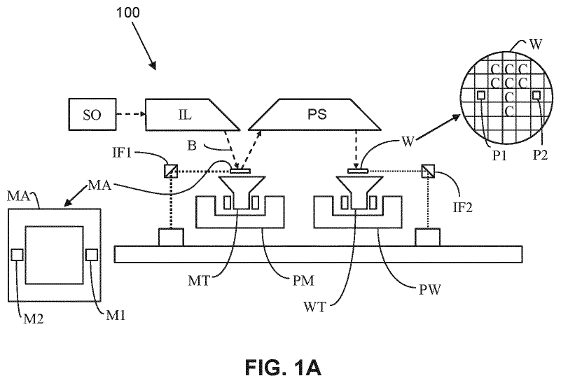

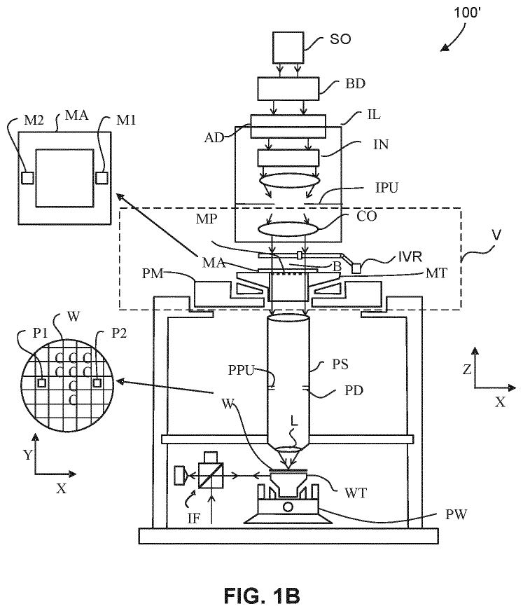

FIGS. 1A and 1B show schematic illustrations of a lithographic apparatus 100 and lithographic apparatus 100′, respectively, in which embodiments of the present disclosure may be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL may include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT may use mechanical, vacuum, electrostatic, or other clamping techniques to hold the patterning device MA. The support structure MT may be a frame or a table, for example, which may be fixed or movable, as required. By using sensors, the support structure MT may ensure that the patterning device MA is at a desired position, for example, with respect to the projection system PS.

The term “patterning device” MA should be broadly interpreted as referring to any device that may be used to impart a radiation beam B with a pattern in its cross-section, such as to create a pattern in the target portion C of the substrate W. The pattern imparted to the radiation beam B may correspond to a particular functional layer in a device being created in the target portion C to form an integrated circuit.

The terms “inspection apparatus,” “metrology system,” or the like may be used herein to refer to, e.g., a device or system used for measuring a property of a structure (e.g., overlay error, critical dimension parameters) or used in a lithographic apparatus to inspect an alignment of a wafer (e.g., alignment apparatus).

The patterning device MA may be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which may be individually tilted so as to reflect an incoming radiation beam in different directions. The tilted mirrors impart a pattern in the radiation beam B, which is reflected by a matrix of small mirrors.

The term “projection system” PS may encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment may be used for EUV or electron beam radiation since other gases may absorb too much radiation or electrons. A vacuum environment may therefore be provided to the whole beam path with the aid of a vacuum wall and vacuum pumps.

Lithographic apparatus 100 and/or lithographic apparatus 100′ may be of a type having two (dual stage) or more substrate tables WT (and/or two or more mask tables). In such “multiple stage” machines, the additional substrate tables WT may be used in parallel, or preparatory steps may be carried out on one or more tables while one or more other substrate tables WT are being used for exposure. In some situations, the additional table may not be a substrate table WT.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIGS. 1A and 1B, the illuminator IL receives a radiation beam from a radiation source SO. The source SO and the lithographic apparatus 100, 100′ may be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO may be an integral part of the lithographic apparatus 100, 100′, for example, when the source SO is a mercury lamp. The source SO and the illuminator IL, together with the beam delivery system BD, if required, may be referred to as a radiation system.

The illuminator IL may include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator may be adjusted. In addition, the illuminator IL may comprise various other components (in FIG. 1B), such as an integrator IN and a condenser CO. The illuminator IL may be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT may be moved accurately (for example, so as to position different target portions C in the path of the radiation beam B). Similarly, the first positioner PM and another position sensor IF1 may be used to accurately position the patterning device (for example, mask) MA with respect to the path of the radiation beam B. Patterning device (for example, mask) MA and substrate W may be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the substrate W. For example, the mask pattern MP may include an array of lines and spaces. A diffraction of radiation at the array and different from zeroth order diffraction generates diverted diffracted beams with a change of direction in a direction perpendicular to the lines. Undiffracted beams (i.e., sσ-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture, by means of a lens or lens group L, not only the zeroth order diffracted beams, but also first-order or first- and higher-order diffracted beams (not shown). In some embodiments, dipole illumination for imaging line patterns extending in a direction perpendicular to a line may be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some embodiments, astigmatism aberration may be reduced by providing radiation poles (not shown) in opposite quadrants of the illumination system pupil IPU. Further, in some embodiments, astigmatism aberration may be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the substrate table WT may be moved accurately (for example, so as to position different target portions C in the path of the radiation beam B). Similarly, the first positioner PM and another position sensor (not shown in FIG. 1B) may be used to accurately position the mask MA with respect to the path of the radiation beam B (for example, after mechanical retrieval from a mask library or during a scan).

In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the mask table MT may be connected to a short-stroke actuator only or may be fixed. Mask MA and substrate W may be aligned using mask alignment marks M1, M2, and substrate alignment marks P1, P2. Although the substrate alignment marks (as illustrated) occupy dedicated target portions, they may be located in spaces between target portions (known as scribe-lane alignment marks). Similarly, in situations in which more than one die is provided on the mask MA, the mask alignment marks may be located between the dies.

Mask table MT and patterning device MA may be in a vacuum chamber V, where an in-vacuum robot IVR may be used to move patterning devices such as a mask in and out of vacuum chamber. Alternatively, when mask table MT and patterning device MA are outside of the vacuum chamber, an out-of-vacuum robot may be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

The lithographic apparatus 100 and 100′ may be used in at least one of the following modes:

1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C may be exposed.

2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT may be determined by the (de-) magnification and image reversal characteristics of the projection system PS.

3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO may be employed and the programmable patterning device is updated as required after each movement of the substrate table WT or in between successive radiation pulses during a scan. This mode of operation may be readily applied to maskless lithography that utilizes a programmable patterning device, such as a programmable mirror array.

Combinations and/or variations on the described modes of use or entirely different modes of use may also be employed.

In a further embodiment, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

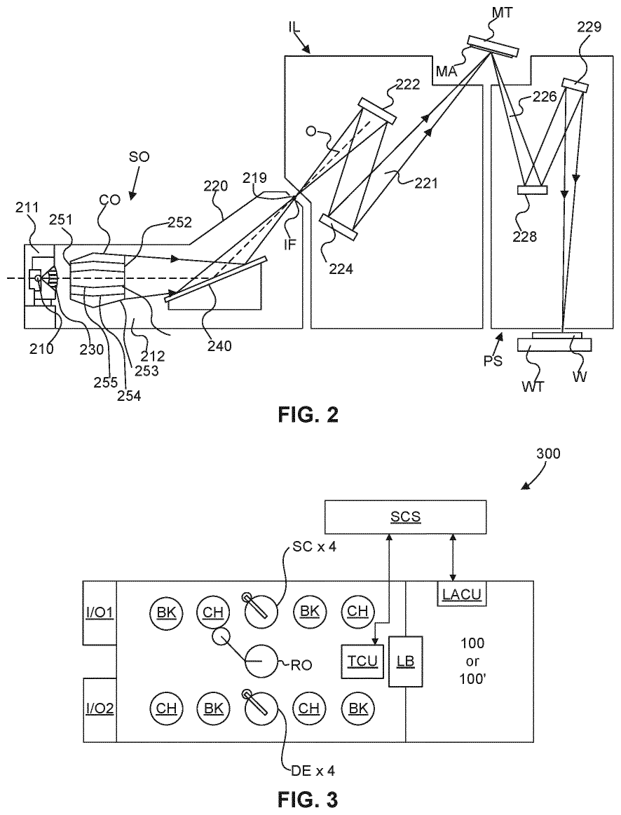

FIG. 2 shows the lithographic apparatus 100 in more detail, including the source collector apparatus SO, the illumination system IL, and the projection system PS. The source collector apparatus SO is constructed and arranged such that a vacuum environment may be maintained in an enclosing structure 220 of the source collector apparatus SO. An EUV radiation emitting plasma 210 may be formed by a discharge produced plasma source. EUV radiation may be produced by a gas or vapor, for example Xe gas, Li vapor, or Sn vapor in which the very hot plasma 210 is created to emit radiation in the EUV range of the electromagnetic spectrum. The very hot plasma 210 is created by, for example, an electrical discharge causing at least a partially ionized plasma. Partial pressures of, for example, 10 Pa of Xe, Li, Sn vapor, or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure.

The collector chamber 212 may include a radiation collector CO, which may be a sσ-called grazing incidence collector. Radiation collector CO has an upstream radiation collector side 251 and a downstream radiation collector side 252. Radiation that traverses collector CO may be reflected off a grating spectral filter 240 to be focused in a virtual source point INTF. The virtual source point INTF is commonly referred to as the intermediate focus, and the source collector apparatus is arranged such that the intermediate focus INTF is located at or near an opening 219 in the enclosing structure 220. The virtual source point INTF is an image of the radiation emitting plasma 210. Grating spectral filter 240 is used in particular for suppressing infra-red (IR) radiation.

Subsequently the radiation traverses the illumination system IL, which may include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown may generally be present in illumination optics unit IL and projection system PS. The grating spectral filter 240 may optionally be present, depending upon the type of lithographic apparatus. Further, there may be more mirrors present than those shown in the FIG. 2, for example there may be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Exemplary Lithographic Cell

FIG. 3 shows a lithographic cell 300, also sometimes referred to a lithocell or cluster, according to some embodiments. Lithographic apparatus 100 or 100′ may form part of lithographic cell 300. Lithographic cell 300 may also include one or more apparatuses to perform pre- and post-exposure processes on a substrate. In some examples, these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses may be operated to maximize throughput and processing efficiency.

### Example Outer Pods

Outer pods described herein withstand atmospheric pressure (i.e., the outer pod can be a vacuum chamber) and are able to interface (seal) directly to other vacuum chambers at its access points. In addition, the outer pods described herein can be opened from the side to facilitate direct access to EUV inner pods (EIPs) with industry handling robots in a horizontal plane. The outer pod may include one or more interfaces to directly pump and vent the outer pod using existing industry hardware. Thus, the contamination is reduced because the EIP is not moved in an atmosphere environment. In some aspects, the outer pods described herein may confirm with mechanical features of pods defined in Semiconductor Equipment and Materials International (SEMI) E100 and SEMI E152 standards. Thus, the outer pods may be transported using existing automation such as overhead hoist transports (OHTs).

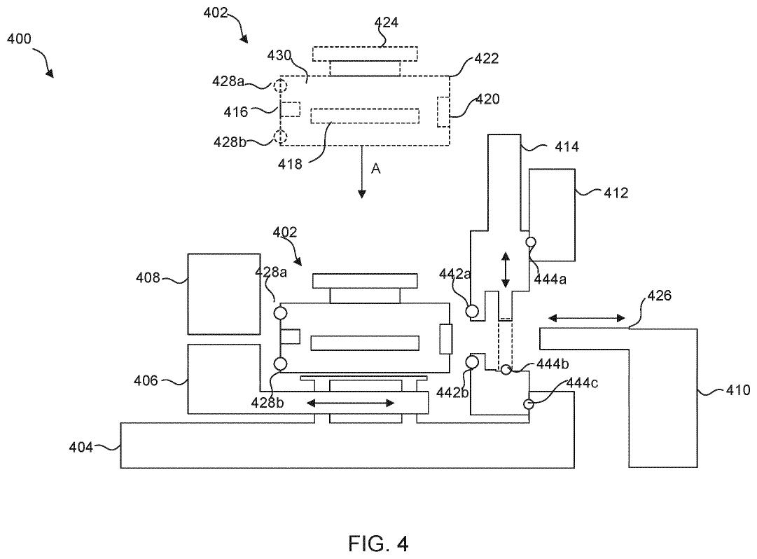

FIG. 4 shows a schematic of a handling system 400, according to some embodiments. Handling system 400 may be a pod handling system (e.g., an inner pod). Handling system 400 may interface with a vacuum environment equipment such as a lithography exposure apparatus (also referred to as a scanner). Handling system 400 may receive an outer pod 402 that houses an inner pod 418 and may transfer inner pod 418 to the lithography exposure apparatus. The lithography exposure apparatus is configured to perform lithography exposing using a reticle stored in inner pod 418.

In one aspect, an outer pod 402 comprises an access door 420 and an outer shell 422. Access door 420 and outer shell 422 form an enclosure space 430. Enclosure space 430 is configured to store inner pod 418 (e.g., EIP). The reticle may be stored in inner pod 418. Access door 420 may configured to provide access to the inside of the enclosure space 430 to place or retrieve inner pod 418. Access door 420 may be in a vertical plane to allow front access (as opposed to bottom or top access). Front access permits interfacing with the vacuum environment via the handler system 400 as described below. Outer pod 402 may also comprise a flange 424. Outer pod 402 is configured be gripped and transported via flange 424. In some aspects, outer pod 402 may be transported using an OHT pod handler module.

In some embodiments, outer shell 422 may include a supply interface 416. Enclosure space 430 may be pumped down to vacuum and purged via supply interface 416. Although one supply interface is shown in FIG. 4, it is understood that outer shell 422 may comprise more than one supply interface. Supply interface 416 may include a valve that controls a gas flow in and out of enclosure space 430 of outer pod 402. Outer shell 422 may include supply seals 428a and 428b. Outer pod 402 may be fully sealed during transportation. In some aspects, enclosure space 430 is capable of maintaining a vacuum pressure ranging from about 1.3 pa to about 4.3 pa. By fully sealing outer pod 402 and processing inner pod 418 in vacuum, the contamination risk from reticle particles, chemical elements, and/or outgassing can be avoided.

Handling system 400 may include an in vacuum robot (IVR) 410 configured to transfer inner pod 418 from inside outer pod 402 to the in vacuum environment. IVR 410 may comprise a gripper 426. Gripper 426 may be configured to move inner pod 418 from enclosure space 430. Gripper 426 may access the interior of outer pod 402 via access door 420. In some aspects, gripper 426 may be configured to move in an XY plane (e.g., move linearly in the y-direction).

In some embodiments, handling system 400 may comprise a gate valve 414. Gate valve 414 may be part of a hoist system. According to some aspects, the hoist system may include a lifting mechanism. For example, gate valve 414 may include cables (or lift belts) (not shown). Gate valve 414 may move in a z-direction. Gate valve 414 may be controlled by a control system. In an open (or lifted state), gate vale 414 provides an opening for IVR 410 to access outer pod 402. Gate valve 414 may comprise sealing interfaces 442a and 442b. In some aspects, sealing interfaces 442a and 442b may be disposed on outer shell 422. Sealing interfaces 442a and 442b may have any shape (e.g., circular).

In some embodiments, outer pod 402 may be positioned on a first support (or stage) 404. In some embodiments, outer pod 402 may be positioned on first support 404 using the OHT pod handler module. For example, outer pod 402 may be dropped on first support 404 as shown by arrow labelled A in FIG. 4.

Handler system 400 may also comprise a second support 412. Gate valve 414 may be coupled to first stage 404 and second stage 414 via bearings 444a, 444b, and 444c.

In some embodiments, a stage 406 may be used to move the pump and vent supplies 408 close to outer pod 402 thus providing a sealing between supplies 408 and outer pod 402. Stage 406 may move in a y-direction. In some aspects, supply seals 428a and 428b may be positioned on an outer surface of outer shell 422 and are configured to provide a seal between pump and vent supplies and stage 406 and outer pod 402.

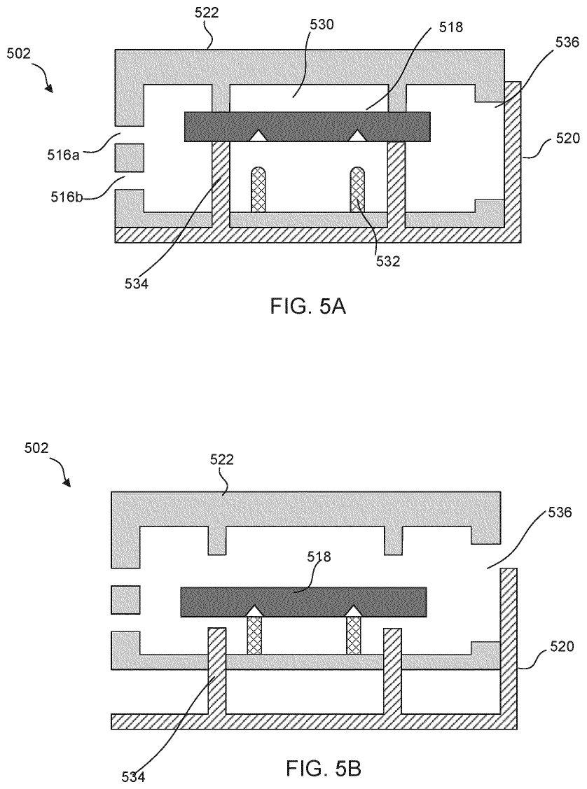

FIG. 5A is a schematic of an outer pod 502, according to some embodiments. In one aspect, outer pod 502 comprises an access door 520 and an outer shell 522. Access door 520 and outer shell 522 form an enclosure space 530. Enclosure space 530 is configured to store inner pod 518. Outer pod 502 may also comprise one or more supports 532 configured to hold inner pod 518 when access door 520 is in a lowered position. In some aspects, access door 520 may be lowered to provide access to enclosure space 530 via an opening 536. Access door 520 may be configured to move linearly in a z-direction. Access door 520 may be actuated by a controller.

In some embodiments, access door 520 may comprise one or more vertical supports 534 (e.g., stubs formed on an inner surface of access door 520). Vertical supports 534 may hold inner pod 518 when the access door is in a closed position. In some aspects, the dimension of opening 536 may be in a range from about 45 mm to about 85 mm. Outer pod 502 may have a width in a range from about 220 mm to about 265 mm. It is to be appreciated the opening 536 and outer pod 502 width can be made larger for larger wafers. For example, the first ranges may be for RSP200 pods, while larger ranges may be needed for larger wafer FOUP containers.

FIG. 5B is a schematic of outer pod 502 with access door 520 in the lowered position, according to some embodiments. An IVR (e.g., IVR 410) may retrieve inner pod 518 from outer pod 502 via opening 536. Outer pod 502 may be pumped down to vacuum and purged before lowering access door 520.

In some embodiments, outer shell 522 may include a first supply interface 516a and a second supply interface 516b. First supply interface 516a may be used to pump down enclosure space 530 to vacuum. Second supply interface 516b may be used to purge enclosure space 530. Once enclosure space 530 is pumped down to vacuum and purged, outer pod 502 may act as a load port to the vacuum environment equipment. Thus, additional equipment such as an EIP handler may not be called for to transfer inner pod 518 to the vacuum environment equipment.

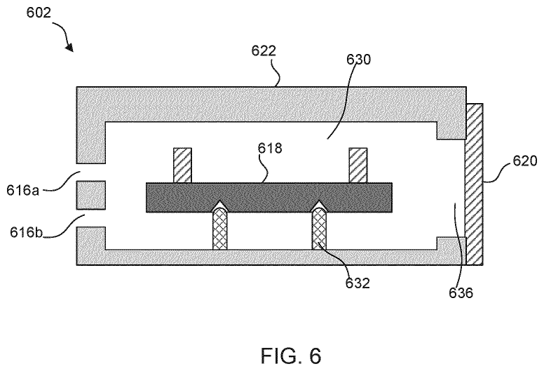

FIG. 6 is a schematic that shows an outer pod 602, according to some embodiments. Outer pod 602 comprises an access door 620 and an outer shell 622. Access door 620 and outer shell 622 form an enclosure space 630. Enclosure space 630 is configured to store inner pod 618. Outer pod 602 may also comprise one or more supports 632 configured to hold inner pod 618. One or more supports 632 may be one or more stubs formed on an inner surface of outer shell 622. In some aspects, access door 620 may be a removable door. Thus, access door 620 may be removed to provide access to enclosure space 630 via opening 636. Access door 620 may be configured to be removed using an external equipment. An IVR (e.g., IVR 410) may retrieve inner pod 618 from outer pod 602 after the access door has been removed.

In some embodiments, outer shell 622 may include a first supply interface 616a and a second supply interface 616b. First supply interface 616a may be used to pump down enclosure space 630 to vacuum. Second supply interface 616b may be used to purge enclosure space 630. Once enclosure space 630 is pumped down to vacuum and purged, outer pod 602 may act as a load port to the vacuum environment equipment. Thus, the IVR may transfer inner pod 618 to the vacuum environment equipment without using additional equipment.

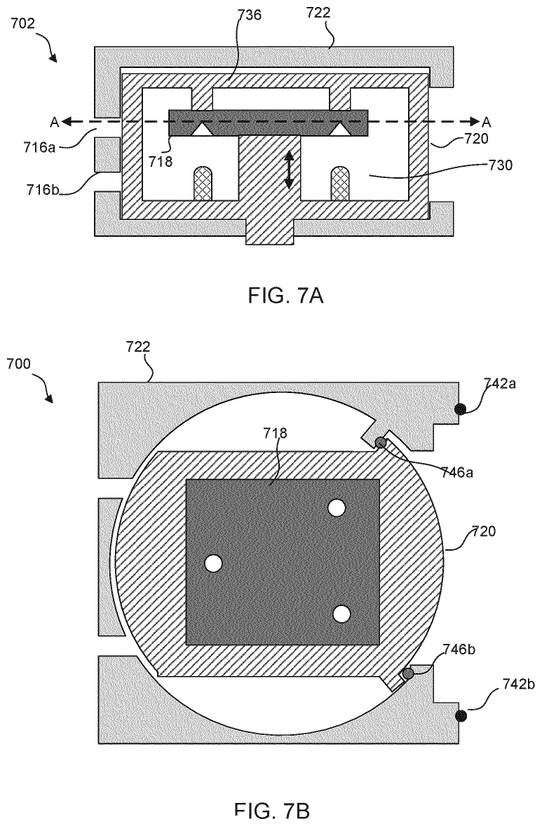

FIG. 7A is a schematic that shows an outer pod 702, according to some embodiments. In some aspects, outer pod 702 comprises an access door 720 and an outer shell 722. Access door 720 and outer shell 722 form an enclosure space 730. Enclosure space 730 is configured to store inner pod 718.

In some embodiments, outer shell 722 may include a first supply interface 716a and a second supply interface 716b. First supply interface 716a may be used to pump down enclosure space 730 to vacuum. Second supply interface 716b may be used to purge enclosure space 730. Once enclosure space 730 is pumped down to vacuum and purged, outer pod 702 may act as a load port to the vacuum environment equipment.

In some embodiments, access door 720 may by a rotary door. Access door 720 may be configured to rotate inside enclosure space 730 (i.e., inside the outer pod 702). Access door 720 may be configured to be rotated using an external apparatus (not shown). In some aspects, access door 720 may be configured to produce a force (in the z-direction) to lock inner pod 718 using a high pitch central screw. In some aspects, access door 720 may include a flexure plate 736 that is configured to produce the z-motion based on a 90 degree motion of the flexure (flexure screw).

FIG. 7B shows a cross-sectional view 700 of the outer pod 702 along the AA line in FIG. 7A, according to some embodiments. In some aspects, FIG. 7B shows inner pod 718 and access door 720. Cross-sectional view 700 shows interior seals 746a and 746b to seal access door 720 with outer shell 722. Outer pod 702 may also include sealing interfaces 742a and 742b to seal the pod with a handling system (e.g., gate valve 414 of handling system 400).

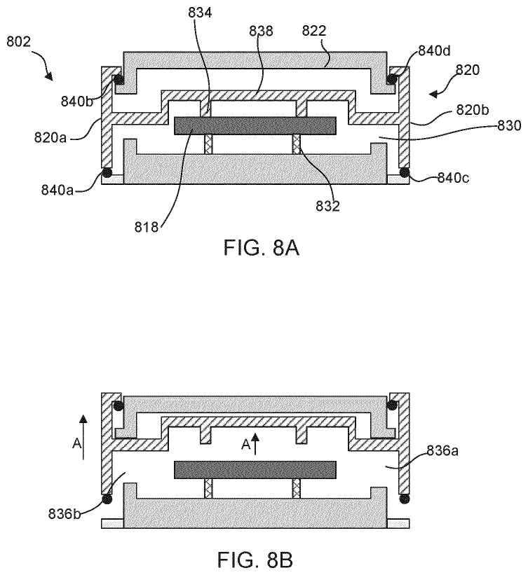

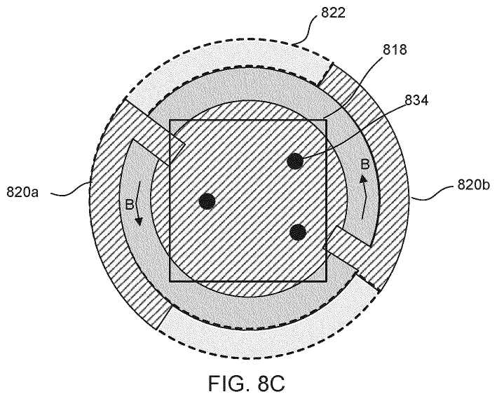

FIG. 8A shows a schematic of an outer pod 802, according to some embodiments. In some aspects, outer pod 802 comprises an access door 820 and an outer shell 822. Access door 820 and outer shell 822 form an enclosure space 830. Enclosure space 830 is configured to store inner pod 818. Outer pod 802 may also comprise one or more supports 832. Supports 832 are configured to hold inner pod 818.

In some embodiments, access door 820 may be a rotary door. Access door 820 may be configured to rotate outside enclosure space 830 (i.e., outside shell 822). Access door 820 may be configured to be rotated using an external apparatus (not shown). Access door 820 may comprise a rear door 820a, a front door 820b, and a plate 838. Rear door 820a and front door 820b are coupled to plate 838. This provides the force to hold inner pod 818 in outer pod 802. Access door 820 may be coupled to the outer shell 822 using soft seals 840a, 840b, 840c, and 840d.

In some embodiments, access door 820 may be configured to move linearly in an upward motion and rotated to provide access to enclosure space 830 via a first opening 836a and a second opening 836b. In some aspects, access door 820 may be lifted in a range from about 10 mm to about 20 mm or about 15 mm. Then, access door 820 may be rotated. First opening 836a may be used to retrieve inner pod 818. Second opening 836b may be used to pump down to vacuum enclosure space 830. In some aspects, second opening 836b may also be used to purge enclosure space 830. Access door 820 may include one or more vertical supports 834. In some aspects, 834 supports can be used to apply force on pod 818. For example, pod 818 can have a top cover with built in spring plungers which, when a force applied, can press onto an inner reticle to hold it by friction preventing the reticle from sliding along x and or y directors from external accelerations.

FIG. 8B shows a schematic of outer pod 802 with access door 820 in a lifted position, according to some embodiments. In some aspects, access door 820 may be configured to move linearly in a vertical movement. For example, access door 820 may move upwardly as shown by arrow labelled A in FIG. 8B.

FIG. 8C is a schematic that shows a cross sectional view of outer pod 802 along the horizontal plane. In some aspects, access door 820 may be rotated in a direction indicated by arrows labelled B in FIG. 8C to provide access to first opening 836a and second opening 836b.

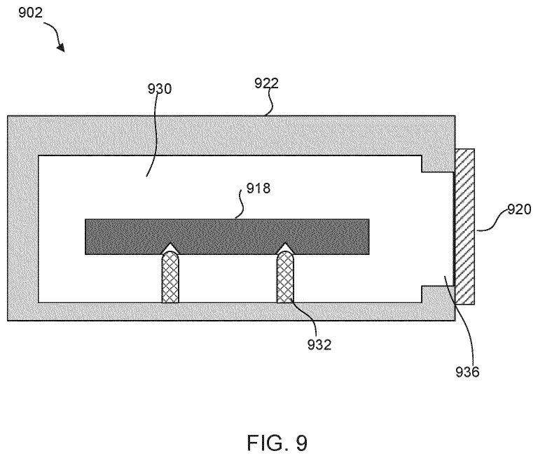

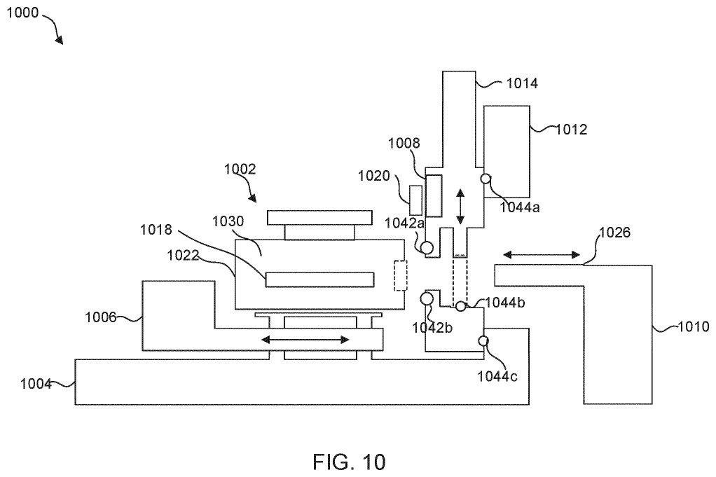

FIG. 9 shows a schematic of an outer pod 902, according to some embodiments. In some aspects, outer pod 902 comprises an access door 920 and an outer shell 922. Access door 920 and outer shell 922 form an enclosure space 930. In some embodiments, enclosure space 930 is configured to store inner pod 918. Outer pod 902 may also comprise one or more supports 932 configured to hold inner pod 918. In some aspects, access door 920 may be a removable door. Thus, access door 920 may be removed to provide access to enclosure space 930 via opening 936. Access door 920 may be configured to be removed using an external equipment. An IVR (e.g., IVR 410) may retrieve inner pod 918 from outer pod 902 after access door 920 has been removed. In some aspects, access door 920 may be removed in a z-direction (e.g., by an external equipment). In some aspects, opening 936 may also be used to pump down to vacuum enclosure space 930 and to purge the enclosure space 930 with a purge gas such as nitrogen. Thus, outer shell 922 may not include a separate supply interface. FIG. 10 shows a schematic of a handling system 1000, according to some embodiments. Handling system 1000 may be a pod handling system (e.g., an inner pod). Handling system 1000 may interface with a vacuum environment equipment such as a lithography exposure apparatus (also referred to as a scanner). Handling system 1000 may receive an outer pod 1002 that houses an inner pod 1018 and may transfer inner pod 1018 to the lithography exposure apparatus. The lithography exposure apparatus is configured to perform lithography exposing using a reticle stored in inner pod 1018. In some embodiments, outer pod 1002 may be similar to outer pod 902 of FIG. 9.

In some embodiments, handling system 1000 may include an IVR 1010 configured to transfer inner pod 1018 from inside outer pod 1002 to the in vacuum environment. IVR 1010 may comprise a gripper 1026. Gripper 1026 may be configured to move inner pod 1018 from enclosure space 1030. Gripper 1026 may access the interior of outer pod 1002 via access door 1020. In some aspects, gripper 1026 is configured to move in an XY plane.

In some embodiments, handling system 1000 may comprise a gate valve 1014. Gate valve 1014 may be part of a hoist system. According to some aspects, the hoist system may include a lifting mechanism. Gate valve 1014 may include cables (or lift belts) (not shown). Gate valve 1014 may move in a z-direction. Gate valve 1014 may be controlled by a control system. In an open (or lifted state), gate vale 1014 provides an opening for IVR 1010 to enclosure space 1030. Gate valve 1014 may comprise sealing interfaces 1042a and 1042b. In some aspects, sealing interfaces 1042a and 1042b may be disposed on outer shell 1022. Sealing interfaces 1042a and 1042b may have any shape (e.g., circular). In some embodiments, gate valve 1014 may comprise supplies 1008 (i.e., pump and purge supplies).

In some embodiments, outer pod 1002 may be positioned on a first support (or stage) 1004. Handler system 1000 may also comprise a second support 1012. Gate valve 1014 may be coupled to first stage 1004 and second stage 1014 via bearings 1044a, 1044b, and 1044c.

In some embodiments, a stage 1006 may be used to provide support for outer pod 1002. In some embodiments, outer pod 1002 may be positioned on first support 1004 using the OHT pod handler module. FIG. 10 shows access door 1020 removed. Access door 1020 may be removed in a z-direction.

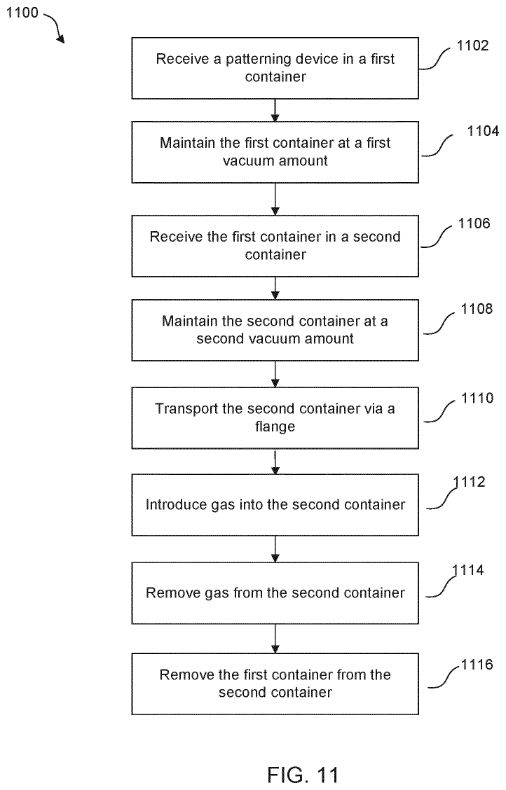

FIG. 11 is a flowchart of a method 1100 for handling inner pods, according to some embodiments. It is to be appreciated that not all operations need be performed, or performed in the order shown.

At step 1102, a patterning device is received (retained or held) in a first container (i.e., inner pod).

At step 1104, the first container may be maintained at a predetermined environment, e.g., clean and controlled environment.

At step 1106, the first container may be received in a second container (e.g. outer pod).

At step 1108, the second container may be maintained at a second vacuum amount, e.g., vacuum range can be about 1.3 to about 4.3 PA.

At step 1110, the second container is transported via a flange located on an exterior of the second container that grips the second container.

At step 1112, gas is introduced into the second container through a purge valve that interfaces with the first external vacuum environment.

At step 1114, gas is removed from the second container through a vacuum valve that interfaces with a first external vacuum environment.

At step 1116, the first container is removed from the second container through an opening of the second container. For example, the first container may be removed via an access door of the second container.

In an optional aspect, the pod can be expressed at vacuum in step 1108, where the sealed to vacuum pod arrives at equipment that introduces a clean gas so that the pod is brought to atmosphere and then the pod is evacuated once again to vacuum. If performed, this step can be used to clean the pod out from the storage state. When this operation is performed, method 1100 moves to step 1116, which is done at vacuum state.

Various embodiments of the present systems and methods are disclosed in the subsequent list of numbered clauses:
1. A system comprising:
   a first container configured to receive a patterning device and to maintain a predetermined environment inside the first container; and
   a second container configured to receive the first container and to maintain a vacuum inside the second container, wherein the second container comprises:
      a flange located on an exterior of the second container, wherein the second container is configured to be gripped and transported via the flange;
      a first end comprising a vacuum valve configured to facilitate removal of gas from the second container and a purge valve configured to facilitate introduction of gas into the second container, wherein the vacuum valve and the purge valve are configured to interface with a first external vacuum environment; and
      a second end opposite the first end, the second end having an opening configured to allow removal of the first container from the second container through the opening.
2. The system of clause 1, wherein the opening is configured to be closed and opened by a door.
3. The system of clause 1, wherein the opening is configured to interface with a second external vacuum environment.
4. The system of clause 2, wherein the door opens or closes in a z-direction.
5. The system of clause 2, wherein a 90° rotation of the door opens or closes the door.
6. The system of clause 5, wherein the 90° rotation is configured to rotate by a screw.
7. The system of clause 2, wherein the door is lifted up and then rotates to open or close the door.
8. A method comprising:
   receiving a patterning device in a first container;
   maintaining the first container at a predetermined environment;
   receiving the first container in a second container;
   maintaining the second container at a vacuum amount;
   transporting the second container via a flange located on an exterior of the second container;
   removing gas from the second container through a vacuum valve that interfaces with a first external vacuum environment;
   introducing gas into the second container through purge valve that interfaces with the first external vacuum environment; and
   removing the first container from the second container through an opening.
9. The method of clause 8, further comprising using a door to open and close the opening.
10. The method of clause 8, further comprising using the opening to interface with a second external vacuum
environment.
11. The method of clause 9, further comprising opening and closing the door in a z-direction.
12. The method of clause 9, further comprising rotating the door 90° to open or close the door.
13. The method of clause 12, further comprising using a screw to allow the 90° rotation.
14. The method of clause 9, further comprising lifting and rotating the door to open and close the door.
15. An outer pod comprising:
   an outer shell;
   a flange located on an exterior of the outer shell, wherein the outer pod is configured to be gripped and transported via the flange;
   an end having an opening, wherein the opening is configured to allow removal of an inner pod stored in the outer pod and to interface with an external vacuum environment; and
   an access door configured to seal the opening.
16. The pod of clause 15, wherein the access door is a rotatable door and a 90° rotation of the access door opens or closes the access door.
17. The pod of clause 16, wherein the access door rotates exterior to the outer shell.
18. The pod of clause 16, wherein the access door rotates inside the outer shell.
19. The pod of clause 15, wherein the access door opens and closes in a z-direction.
20. The pod of clause 15, wherein the access door is detachable from the outer shell to provide access to the opening.

Although specific reference can be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein can be considered as specific examples of the more general terms “substrate” or “target portion”, respectively. The substrate referred to herein can be processed, before or after exposure, in for example a track unit (a tool that typically applies a layer of resist to a substrate and develops the exposed resist) and/or a metrology unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

Although specific reference may have been made above to the use of embodiments of the present disclosure in the context of optical lithography, it will be appreciated that the present disclosure can be used in other applications, for example imprint lithography, and where the context allows, is not limited to optical lithography. In imprint lithography a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present disclosure is to be interpreted by those skilled in relevant art(s) in light of the teachings herein.

The terms “radiation,” “beam of radiation” or the like as used herein can encompass all types of electromagnetic radiation, for example, ultraviolet (UV) radiation (for example, having a wavelength λ of 365, 248, 193, 157 or 126 nm), extreme ultraviolet (EUV or soft X-ray) radiation (for example, having a wavelength in the range of 5-20 nm such as, for example, 13.5 nm), or hard X-ray working at less than 5 nm, as well as matter beams, such as ion beams or electron beams. The terms “light,” “illumination,” or the like can refer to non-matter radiation (e.g., photons, UV, X-ray, or the like). Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some embodiments, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

It is to be appreciated that the Detailed Description section, and not the Summary and Abstract sections, is intended to be used to interpret the claims. The Summary and Abstract sections may set forth one or more but not all exemplary embodiments of the present disclosure as contemplated by the inventor(s), and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

While specific embodiments of the disclosure have been described above, it will be appreciated that embodiments of the present disclosure may be practiced otherwise than as described. The descriptions are intended to be illustrative, not limiting. Thus it will be apparent to one skilled in the art that modifications may be made to the disclosure as described without departing from the scope of the claims set out below.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein.

The breadth and scope of the protected subject matter should not be limited by any of the above-described exemplary embodiments, but should be defined only in accordance with the following claims and their equivalents.

1. A system comprising:
a first container configured to receive a patterning device and to maintain a predetermined environment inside the first container; and
a second container configured to receive the first container and to maintain a vacuum inside the second container, wherein the second container comprises:
a flange located on an exterior of the second container, wherein the second container is configured to be gripped and transported via the flange;
a first end comprising a vacuum valve configured to facilitate removal of gas from the second container and a purge valve configured to facilitate introduction of gas into the second container, wherein the vacuum valve and the purge valve are configured to interface with a first external vacuum environment; and
a second end opposite the first end, the second end having an opening configured to allow removal of the first container from the second container through the opening.

2. The system of claim 1, wherein the opening is configured to be closed and opened by a door.

3. The system of claim 1, wherein the opening is configured to interface with a second external vacuum environment.

4. The system of claim 2, wherein:
the door opens or closes in a z-direction;
a 90° rotation of the door opens or closes the door;
the 90° rotation is configured to rotate by a screw; and
wherein the door is lifted up and then rotates to open or close the door.

5. A method comprising:
receiving a patterning device in a first container;
maintaining the first container at a predetermined environment;
receiving the first container in a second container;
maintaining the second container at a vacuum amount;
transporting the second container via a flange located on an exterior of the second container;
removing gas from the second container through a vacuum valve that interfaces with a first external vacuum environment;
introducing gas into the second container through purge valve that interfaces with the first external vacuum environment; and
removing the first container from the second container through an opening.

6. The method of claim 5, further comprising:
using a door to open and close the opening;
using the opening to interface with a second external vacuum environment; and
opening and closing the door in a z-direction.

7. The method of claim 6, further comprising rotating the door 90° to open or close the door.

8. The method of claim 7, further comprising using a screw to allow the 90° rotation.

9. The method of claim 6, further comprising lifting and rotating the door to open and close the door.

10. An outer pod comprising:
an outer shell;
a flange located on an exterior of the outer shell, wherein the outer pod is configured to be gripped and transported via the flange;
an end having an opening, wherein the opening is configured to allow removal of an inner pod stored in the outer pod and to interface with an external vacuum environment; and
an access door configured to seal the opening.

11. The pod of claim 10, wherein the access door is a rotatable door and a 90° rotation of the access door opens or closes the access door.

12. The pod of claim 11, wherein the access door rotates exterior to the outer shell.

13. The pod of claim 11, wherein the access door rotates inside the outer shell.

14. The pod of claim 10, wherein the access door opens and closes in a z-direction.

15. The pod of claim 10, wherein the access door is detachable from the outer shell to provide access to the opening.
